(19) United States
(12) Patent Application Publication
(10) Pub. No.: US 2020/0048140 A1
(43) Pub. Date: Feb. 13, 2020

(54) GLASS FRIT, CONDUCTIVE PASTE AND USE OF THE CONDUCTIVE PASTE

(71) Applicant: BASF SE, Ludwigshafen am Rhein (DE)

(72) Inventors: Ming Yi HSU, Taoyuan (TW); Charles PAN, Taichung City (TW); Li Fu HUANG, Taoyuan (TW); Panneerselvam MARUDHACHALAM, Ludwigshafen (DE); Yi Hung HSIEH, Taoyuan (TW)

(73) Assignee: BASF SE, Ludwigshafen am Rhein (DE)

(21) Appl. No.: 16/486,047

(22) PCT Filed: Feb. 13, 2018
(86) PCT No.: PCT/EP2018/053489

§ 371 Date: Aug. 14, 2019

(30) Foreign Application Priority Data
Feb. 15, 2017 (EP) 17156243.2

(51) Int. Cl. C03C 4/14; H01L 31/0224; H01B 1/22; H01B 1/16; C03C 8/10; C03C 8/18; C03C 3/07; C03C 8/22

(52) U.S. Cl. CPC C03C 4/14; H01L 31/022425; H01B 1/22; H01B 1/16; C03C 2204/00; C03C 8/18; C03C 3/07; C03C 8/22; C03C 2205/00; C03C 8/10

(57) ABSTRACT

The invention relates to a glass frit being a mixture of a first glass frit comprising tellurium oxide and bismuth oxide as main components and a second glass frit comprising tellurium oxide and lead oxide as main components, wherein the mixture of the first glass frit and the second glass frit comprises 40 to 55% by weight of tellurium oxide, 15 to 25% by weight of lead oxide and 5 to 15% by weight of bismuth oxide. The invention further relates to a conductive paste for forming electrodes on a semiconductor substrate, the paste comprising 85 to 92% by weight of an electrically conductive metal, 1.5 to 3.5% by weight of the glass frit and organic medium. The conductive paste is used for forming electrically conductive grid lines on semiconductor substrates for solar cells.

The invention relates to a conductive paste comprising an electrically conductive metal, a glass frit and organic medium.

Conductive inks or pastes are used to form electrodes, such as silver gridlines and bus bars, on the surface of silicon solar cells or photovoltaic cells. Photovoltaic (“PV”) cells convert sunlight into electricity by promoting charge carriers in the valence band of a semiconductor into the conduction band of the semiconductor. The interaction of photons from incident sunlight with doped semiconductor materials forms electron-hole charge carriers. These electron-hole pair charge carriers migrate in the electric field generated by the p-n semiconductor junction and are collected by electrodes applied to the surface of the semiconductor, through which the current flows to the external circuit.

Modern crystalline silicon solar cells are typically coated with at least one thin passivation layer for the purpose of reducing electron-hole recombination caused by dangling bonds at the silicon wafer surface. Crystalline solar cells are also usually coated with anti-reflection coatings to minimize reflected light and promote light absorption. Unfortunately passivation layers and antireflection coatings are typically electrical insulators and thus prevent charge carriers (electrons or holes) from transferring from the substrate to the corresponding electrode. Solar cells are typically covered by the passivation layer and/or anti-reflection coating before a conductive paste is applied. Conductive pastes are commonly applied by screen printing, offset printing, ink jet printing, laser printing or extrusion. The aforementioned passivation layers can be amorphous or crystalline. The thickness and stoichiometry of such layers can be varied in order to tune the performance. Anti-reflection coatings often comprise silicon nitride or titanium oxide. Such antireflective coatings can be amorphous or crystalline. The thickness and stoichiometry of such coatings can also be varied in order to tune the performance. Such antireflective coatings can also be partially hydrogenated. Amorphous hydrogenated silicon nitride coatings also act as passivation layers for n-type silicon surfaces. Some solar cell architectures use multiple layers to optimize the cell passivation and antireflective properties. Such “dielectric stacks” are commonly used in the industry and often consist of a-Si_{y}Nₓ:H layers on top of very thin (<3 nm) AlOₓ, SiOₓ or SiC layers. In particular, such dielectric stacks are commonly used on top of p-type silicon surfaces as AlOₓ, SiOₓ and SiC provide excellent passivation of these types of solar cells whereas silicon nitride variants do not.

An electrode for a solar cell optimally provides low electrical resistance so that the percentage of incident sunlight converted to usable electrical energy is maximized. The amount of sunlight converted to electricity is referred to as “efficiency”. Both the resistivity of the electrode as well as the contact resistance between the electrode and the silicon wafer have a strong influence on solar cell efficiency. The resistivity and contact resistance should be minimized in order to improve solar cell efficiency.

The electrode can reduce the efficiency of a solar cell by introducing undesirable contaminants or defects into the silicon. Such defects are recombination sources and reduce the cell efficiency and thus reduce the amount of power that can be generated by a cell. Thus the performance of the cell is improved by using electrode compositions that do not introduce recombination sources.

Conductive pastes are used to form electrodes, conductive grids or metal contacts. Conductive pastes as described for example in U.S. Pat. No. 8,889,980 typically include one or more glass frits, a conductive species, such as silver particles, and an organic medium. In some cases the glass frit may be partially crystalline. To form the electrode, conductive pastes are printed onto the antireflective coating in a pattern of grid lines or other pattern by screen printing or another suitable process. The substrate is then fired, during which electrical contact is made between the grid lines and the substrate. Typically the firing is done in a belt furnace in air or an oxygen containing atmosphere. Performance of such electrode pastes can be optimized by adjusting the firing temperature and time. Typically peak firing temperatures are between 600° C. and 950° C. Typically the firing time for such cells can vary between about 30 seconds to several minutes.

As mentioned previously, the anti-reflective coating enhances light absorption but also acts as an insulator which impairs the charge carriers from flowing from the substrate to the electrode. Accordingly, during the firing cycle the conductive paste should etch at least part of the antireflective coating and part of any passivation layer to form electrodes having low contact resistance. To accomplish this, conductive pastes incorporate at least one glass frit. The glass frit performs multiple functions. First, glass frit will aid with sintering metal particles, thus improving conductivity of the electrode and enabling solder connections to be made. Second, the glass frit will interact with antireflection coatings and passivation layers to reduce contact resistance between the formed metal electrode and the substrate. Third, the glass provides the medium for development of metal colloids which can further enhance charge carrier collection. Fourth the glass provides adhesion to the substrate. Fifth the glass provides some added chemical durability to the electrode for example moisture resistance. From U.S. Pat. No. 7,736,546 it is known that particularly TeO₂ containing glass frits can be effective for use in pastes used for making electrodes on silicon solar cells.

During the firing process the glass frit liquefies, and tends to flow within the open microstructure of the electrode paste, coating the silver particles and the anti-reflective coating on the substrate. It is believed that the melted glass dissolves and/or oxidizes at least part of the antireflective coating and any passivation layer as well as some of the metal particles contained in the paste. As the firing process proceeds to the cooling stage, dissolved metal silver, ionic silver or silver oxide can recrystallize to metallic silver at the silicon surface. As a result, some of these silver crystallites are able to penetrate the antireflective layer and form a low contact resistance electrode with the substrate. This enables at least some direct contact between the substrate and the sintered bulk metal of the paste. If the interfacial glass layer near the substrate is thin enough and/or contains metal colloids, it is believed that the contact resistance between the electrode and the substrate can be enhanced. This process is referred to as “fire-through” and facilitates a low resistivity, low contact resistance contact with a strong bond between conductive grid or metal contact and the substrate.

However, it is a disadvantage of all conductive pastes that due to high firing temperatures a wafer warping may occur and further that glass frits allowing lower firing temperatures show inferior penetration properties of the antireflection and passivation layers resulting in lower efficiency of the solar cell.

Therefore, it has been an object of the present invention to provide a glass frit for a conductive paste for forming electrodes on a semiconductor substrate and a conductive paste which allows lower firing temperature and shows good penetration properties of the antireflection and passivation layers.

This object is achieved by a glass frit being a mixture of a first glass frit comprising tellurium oxide and bismuth oxide as main components and a second glass frit comprising tellurium oxide and lead oxide as main components, wherein the mixture of the first glass frit and the second glass frit comprises 40 to 55% by weight of tellurium oxide, 15 to 25% by weight of lead oxide and 5 to 15% by weight of bismuth oxide.

The object is further achieved by a conductive paste for forming electrodes on a semiconductor substrate, the paste comprising:
(a) 85 to 92% by weight of an electrically conductive particles,
(b) 1.5 to 3.5% by weight of the glass frit being a mixture of a first glass frit comprising tellurium oxide and bismuth oxide as main components and a second glass frit comprising tellurium oxide and lead oxide as main components, wherein the mixture of the first glass frit and the second glass frit comprises 40 to 55% by weight of tellurium oxide, 15 to 25% by weight of lead oxide and 5 to 15% by weight of bismuth oxide,
(c) and organic medium.

Surprisingly it had been shown that using a glass frit being composed of a mixture of a first glass frit and a second glass frit, wherein the first glass frit is a glass frit comprising tellurium oxide and bismuth oxide as main components and the second glass frit is a glass frit comprising tellurium oxide and lead oxide in a paste for producing electrodes on semiconductor substrates allows firing at lower temperatures without losses in efficiency. This is particularly surprising due to the fact that the amount of lead oxide in the mixture which lowers the melting point is much smaller than in glass frits which have been used in known pastes.

In the mixture, the first glass frit is an adhesion promoter and acts as a sintering aid. On the other hand, the second glass frit has promising electric resistance, a lower firing temperature and a wide firing window.

In one embodiment of the invention, the first glass frit comprises 40 to 70% by weight of TeO₂ and 0.1 to 15% by weight of Bi₂O₃. In a preferred embodiment, the first glass frit comprises 50 to 70 by weight of TeO₂ and 5 to 15% by weight of Bi₂O₃. Particularly preferably, the first glass frit comprises 60 to 70 by weight of TeO₂ and 5 to 10% by weight of Bi₂O₃.

Besides TeO₂ and Bi₂O₃ the first glass frit preferably comprises at least one further oxidic compound. The at least one further oxidic compound for example is selected from 0.1 to 15% by weight of SiO₂, 0.1 to 15% by weight of ZnO, 0.1 to 15% by weight of WO₃ and 0 to 10% by weight of Li₂O. It is further preferred when the first glass frit comprises 5 to 15% by weight of SiO₂, 5 to 15% by weight of ZnO, 5 to 15% by weight of WO₃ and 0 to 5% by weight of Li₂O and particularly preferred, when the first glass frit comprises 5 to 10% by weight of SiO₂, 5 to 10% by weight of ZnO, 5 to 10% by weight of WO₃ and 0 to 4% by weight of Li₂O. In a particularly preferred embodiment, the first glass frit comprises all of the afore mentioned oxidic compounds SiO₂, ZnO, WO₃ and Li₂O.

In a further embodiment, the first glass frit additionally comprises one or more of Cs₂O₃, MgO, V₂O₅, ZrO₂, Mn₂O₃, Ag₂O, In₂O₃, SnO₂, NiO, Cr₂O₃, B₂O₃, Na₂O, Al₂O₃ and CaO, each in an amount in the range from 0 to 10% by weight, preferably in an amount in the range from 0 to 5% by weight and particularly preferably in an amount in the range from 0.01 to 1% by weight.

The second glass frit preferably comprises 40 to 70% by weight of TeO₂ and 5 to 30% by weight of PbO. Further preferably, the second glass frit comprises 40 to 60% by weight of TeO₂ and 15 to 30% by weight of PbO. Particularly preferably, the first glass frit comprises 45 to 55% by weight of TeO₂ and 20 to 30% by weight of PbO.

Besides TeO₂ and PbO the second glass frit may comprise further oxidic compounds. The further oxidic compounds are for example 0.1 to 15% by weight of Bi₂O₃, 0.1 to 15% by weight of SiO₂, 0.1 to 10% by weight of ZnO, 0.1 to 10% by weight of WO₃ and 0.1 to 10% by weight of Li₂O. It is further preferred when the second glass frit comprises 5 to 15% by weight of Bi₂O₃, 5 to 15% by weight of SiO₂, 0.1 to 5% by weight of ZnO, 0.1 to 5% by weight of WO₃ and 0.1 to 5% by weight of Li₂O and particularly preferred, when the first glass frit comprises 10 to 15% by weight of Bi₂O₃, 5 to 10% by weight of SiO₂, 0.1 to 3% by weight of ZnO, 0.1 to 3% by weight of WO₃ and 0.1 to 3% by weight of Li₂O.

In a further embodiment, the second glass frit additionally comprises one or more of Cs₂O₃, MgO, V₂O₅, ZrO₂, Mn₂O₃, Ag₂O, In₂O₃, SnO₂, NiO, Cr₂O₃, B₂O₃, Na₂O, Al₂O₃ and CaO, each in an amount in the range from 0 to 10% by weight, preferably in the range from 0 to 5% by weight and particularly preferably in a range from 0.01 to 1% by weight.

The glass frit particularly can be used for producing an electrically conductive paste. Such pastes are used for example for printing electrodes or grid lines on semiconductor substrates for producing solar cells. Generally such pastes are printed onto the semiconductor substrate by screen printing processes. Besides screen printing, any other printing process known to a skilled person as ink jet printing, offset printing, laser printing and extrusion can be used. However, it is preferred to print the electrodes or grid lines by screen printing.

After printing the electrodes or grid lines, the semiconductor substrate with the electrodes and/or grid lines printed thereon, is fired. During firing the glass frit melts and particularly when the paste is used for printing electrodes or grid lines on a semiconductor for producing a solar cell, the melted glass frit dissolves antireflection coatings and passivation layers and thus allows forming of a low contact resistance electrode with the semiconductor substrate. When using the inventive glass frit as described above, it is possible to perform the firing step at lower temperatures than with electrically conductive pastes as known from the state of the art. Particularly, it is possible to perform the firing step at a temperature below 920° C., particularly in a range between 850 and 910° C.

To achieve electrically conductive grid lines or electrodes, the conductive paste comprises electrically conductive particles. During firing, the electrically conductive particles sinter and electrical conductivity is achieved by contact of the electrically conductive particles.

The electrically conductive particles present in the electrically conductive paste may be particles of any geometry composed of any electrically conductive material. Preferably, the electrically conductive particles comprise carbon, silver, gold, aluminum, platinum, palladium, tin, nickel, cadmium, gallium, indium, copper, zinc, iron, bismuth, cobalt, manganese, molybdenum, chromium, vanadium, titanium, tungsten, or mixtures or alloys thereof or are in the form of core-shell structures thereof. Preferred as material for the electrically conductive particles are silver or aluminum, particularly silver due to good conductivity.

If the electrically conductive particles are silver particles, it is further possible that some of the silver is added as silver oxide (Ag₂O), as a silver salt, e.g. silver chloride (AgCl), silver fluoride (AgF), silver nitrate (AgNO₃), silver acetate (AgC₂H₃O₂), or silver carbonate (Ag₂CO₃). Silver containing resonates or silver containing metallo-organic compounds can also be effectively introduced to the paste.

The mean particle size of the electrically conductive particles preferably is in the range from 10 nm to 100 μm. More preferably, the mean particle size is in the range from 100 nm to 50 μm and particularly preferred, the mean particle size is in the range from 500 nm to 10 μm. The electrically conductive particles may have any desired form known to those skilled in the art. For example, the particles may be in the form of flakes, rods, wires, nodules, spheres or any mixtures thereof. Spherical particles in context of the present invention also comprise particles with a real form which deviates from the ideal spherical form. For example, spherical particles, as a result of the production, may also have a droplet shape or be truncated. Suitable particles which can be used to produce the conductive paste are known to those skilled in the art and are commercially available. Particularly preferably, spherical silver particles are used. The advantage of the spherical particles is their improved rheological behavior compared to irregular shaped particles.

The proportion of electrically conductive particles in the composition is in the range from 30 to 97% by weight. The proportion is preferably in the range from 70 to 95% by weight and particularly preferred in the range from 85 to 92% by weight. This weight percentage of solid particles is often referred as solids content.

The particle shapes and sizes do not change the nature of this invention. Particles can be used as mixtures of different shapes and sizes. It is known to those skilled in the art that the particles with mixtures of different shapes or sizes can result in higher or lower viscosity when they are dispersed in the same organic medium. In such case, it is known to those skilled in the art that the organic medium needs to be adjusted accordingly. The adjustment can be but is not limited to variations of solids content, solvent content, polymer content, thixotrope content and/or surfactant content. As an example, typically when nano-sized particles are used to replace micronsized particles, the solids content has to be reduced to avoid an increase of the viscosity of the paste, which results in higher contents of organic components.

The electrically conductive particles, especially when made of a metal, generally are coated with organic additives in the course of production. In the course of preparation of the composition for printing conductor tracks, the organic additives on the surface are typically not removed, such that they are then also present in the conductive paste. The proportion of additives for stabilization is generally not more than 10% by weight, based on the mass of particles. The additives used to coat the electrically conductive particles may, for example, be fatty amines or fatty amides, for example dodecylamine. Further additives suitable for stabilizing the particles are, for example, octylamine, decylamine, and polyethyleneimines. Another embodiment may be fatty acids, fatty acid esters, with or without epoxylation, for example, lauric acid, palmitic acid, oleic acid, stearic acid, or a salt thereof. The coating on the particles does not change the nature of this invention.

According to the invention, the paste further comprises an organic medium. The organic medium generally is selected from the group comprising solvents, binders, dispersants, thixotropes and mixtures thereof.

To achieve a paste, at least part of the organic medium has to be liquid. Suitable liquids for example comprise organic solvents.

In one embodiment of the invention, the organic solvent comprises one or more organic solvents selected from liquid organic components having at least one oxygen atom. The liquid organic component having at least one oxygen atom is selected from alcohol, ester alcohol, glycol, glycol ether, ketone, fatty acid ester or terpene derivatives. Further suitable liquid organic components are acetates, propionates and phthalates.

The liquid organic component for example may be benzyl alcohol, texanol, ethyl lactate, diethylene glycol monoethyl acetate, diethylene glycol monobutylether, diethylene glycol dibutylether, diethylene glycol monobutylether acetate, butyl cellosolve, butyl cellosolve acetate, propylene glycol monometylether, propylene glycol monomethylether acetate, dipropylene glycol monomethylether, propylene glycol monomethylpropionate, ethylether propionate, dimethylamino formaldehyde, methylethylketone, gamma-butyrolactone, ethyl linoleate, ethyl linolenate, ethyl myristate, ethyl oleate, methyl myristate, methyl linoleate, methyl linolenate, methyl oleate, dibutyl phthalate, dioctyl phthalate, terpineol, isopropanol, tridecanol and 2,2,4-trimethyl-1,3-pentanediol monoisobutyrate, dibutyl carbitol or terpenes such as pine oil.

The solvent being a liquid organic component having at least one oxygen atom can be used in the conductive paste either as single solvent or as a solvent mix.

It further is possible to utilize solvents that also contain volatile liquids to promote fast setting after application to the substrate.

Besides solvents, the organic medium may comprise organic binders. The organic binder is used to adhere the electrically conductive paste on the semiconductor substrate prior to firing. During firing all organic compounds are evaporated due to the high temperature and adherence of the electrodes and/or grid lines formed during firing is achieved by the glass frit.

The amount of organic binders can be in a range from 0.1 to 10% by weight. The organic binder can be selected from natural or synthetic resins and polymers. As known to those skilled in the art, selections are based on but not limited to solvent compatibility and chemical stability. For example, the common binders as disclosed in the prior art comprise cellulose derivatives, acrylic resin, phenolic resin, urea-formaldehyde resin, alkyd resin, aliphatic petroleum resin, melamine formaldehyde resin, rosin, polyethylene, polypropylene, polystyrene, polyether, polyurethane, polyvinyl acetate and copolymers thereof.

The paste additionally may comprise from 0.1 to 10% by weight of at least one additive selected from surfactants, thixotropic agents, plasticizers, solubilizers, defoamers, desiccants, crosslinkers, complexing agents and/or conductive polymer particles. The additives may be used individually or as a mixture of two or more of them.

When a surfactant is used as an additive, it is possible to use only one surfactant or more than one surfactant. In principle, all surfactants which are known to those skilled in the art or are described in the prior art, can be suitable. Preferred surfactants are singular or plural compounds, for example anionic, cationic, amphoteric or nonionic surfactants. However, it is also possible to use polymers with pigment-affinitive anchor groups, which are known to a skilled person as surfactants.

In case the electrically conductive particles are pre-coated with a surfactant, the conductive paste may not comprise an additional surfactant as additive.

The electrically conductive paste can be used for all applications where electrodes or grid lines are printed onto semiconductor substrates. However, it is particularly preferred to use the electrically conductive paste for forming electrically conductive grid lines on semiconductor substrates for solar cells.

### EXAMPLES

A conductive paste has been prepared by mixing 90% by weight silver powder having a mean particle size of 3% by weight of glass frit and 7% by weight organic medium. The composition of the first and the second glass frit is shown in table 1.

TABLE 1
Composition of the glass frit

| component | Mixture #1 | Mixture #2 | Mixture #3 |
|---|---|---|---|
| TeO₂ | 65 | 55 | 50 |
| PbO | 5 | 20 | 25 |
| Bi₂O₃ | 10 | 11 | 12 |
| SiO₂ | 7 | 6 | 5 |
| ZnO | 4 | 2 | 1 |

The pastes were applied to 6″ multi-crystalline (Table 2) and mono-crystalline (Table 3) wafers and with a sheet resistance of 80Ω/□ phosphorous-doped emitter on a p-type base. The solar cells used were textured by isotropic acid etching and had an 80 nm anti-reflection coating (ARC) of SiNX:H. For each paste, the mean values of the efficiency and fill factor for 15 pieces of silicon wafer are shown. Each sample was made by screen-printing using a micro-tec MT650 printer set with a squeegee speed of 250 mm/sec. The screen used had a pattern of 105 finger lines with a 32 μm opening and 4 bus bar with a 1.0 mm opening on a 14 μm emulsion in a screen with 360 mesh and 16 μm wires. A commercially available Al paste was printed on the non-illuminated (back) side of the device. The Al paste was printed with 5 μm emulsion in a screen with 250 mesh and 35 μm wires.

The device with the printed patterns was then dried in a drying oven with a 250° C. peak temperature. The substrates were then fired sun-side up with a CF-SL Despatch 6-zone IR furnace using a 635 cm/min belt speed and 920° C. (as shown in Table 2), and 900° C., 910 C and 920° C. (as shown in Table 3), as setting temperature of the 6^{th} zone in the furnace.

The solar cells built according to the method described herein were tested for conversion efficiency.

In an embodiment, the solar cells built according to the method described herein were placed in a commercial I-V tester for measuring efficiencies (halm gmbh, cetisPV-Celltest3). The Xe Arc lamp in the I-V tester simulated the sunlight with a known intensity, AM 1.5, and irradiated the front surface of the cell. The tester used a four-contact method to measure current (I) and voltage (V). Solar cell efficiency (Eta), open-circuit voltage (Voc) and fill factor (FF) were calculated from the I-V curve.

As can be seen from table 2, the inventive paste shows noticeably higher solar cell efficiency as comparable to a reference paste. Table 3 further shows the inventive paste gives promising solar cell efficiency without loss of fill factor over the firing temperature range.

TABLE 2
Voc (open-circuit voltage), Solar cell efficiency and fill factor
compared to a reference paste

| | Setting | | | |
|---|---|---|---|---|
| Paste | temperature (° C.) | Voc (mV) | FF (%) | Eta (%) |
| Reference paste | 920 | 629.6 | 79.7 | 18.0 |
| Mixture #1 | 920 | 630.0 | 79.4 | 18.1 |
| Mixture #2 | 920 | 630.6 | 79.7 | 18.3 |
| Mixture #3 | 920 | 631.0 | 79.7 | 18.2 |

TABLE 3
Voc (open-circuit voltage), Solar cell efficiency and fill factor
over firing range.

| | Setting | | | |
|---|---|---|---|---|
| Mixture | temperature (° C.) | Voc (mV) | FF (%) | Eta (%) |
| Mixture #2 | 900 | 643.0 | 80.5 | 19.7 |
| Mixture #2 | 910 | 643.7 | 80.6 | 19.8 |
| Mixture #2 | 920 | 642.2 | 80.6 | 19.7 |

1: A glass frit, comprising a mixture of a first glass frit comprising tellurium oxide and bismuth oxide as main components and a second glass frit comprising tellurium oxide and lead oxide as main components,
wherein the mixture of the first glass frit and the second glass frit comprises 40 to 55% by weight of tellurium oxide, 15 to 25% by weight of lead oxide and 5 to 15% by weight of bismuth oxide.

2: The glass frit of claim 1, wherein the first glass frit comprises 40 to 70% by weight of TeO₂ and 0.1 to 15% by weight of Bi₂O₃.

3: The glass frit of claim 2, wherein the first glass frit further comprises 0.1 to 15% by weight of SiO₂, 0.1 to 15% by weight of ZnO, 0.1 to 15% by weight of WO₃ and 0 to 10% by weight of Li₂O.

4: The glass frit of claim 3, wherein the first glass frit additionally comprises one or more of Cs₂O₃, MgO, V₂O₅, ZrO₂, Mn₂O₃, Ag₂O, In₂O₃, SnO₂, NiO, Cr₂O₃, B₂O₃, Na₂O, Al₂O₃ and CaO, each in an amount in a range of from 0 to 10% by weight.

5: The glass frit of claim 1, wherein the second glass frit comprises 40 to 70% by weight of TeO₂ and 5 to 30% by weight of PbO.

6: The glass frit of claim 5, wherein the second glass frit further comprises 0.1 to 15% by weight of Bi₂O₃, 0.1 to 15% by weight of SiO₂, 0.1 to 10% by weight of ZnO, 0.1 to 10% by weight of WO₃ and 0.1 to 10% by weight of Li₂O.

7: The glass frit of claim 6, wherein the second glass frit additionally comprises one or more of Cs₂O₃, MgO, V₂O₅, ZrO₂, Mn₂O₃, Ag₂O, In₂O₃, SnO₂, NiO, Cr₂O₃, B₂O₃, Na₂O, Al₂O₃ and CaO, each in an amount in a range of from 0 to 10% by weight.

8: A conductive paste, comprising:
(a) 85 to 92% by weight of an electrically conductive metal,
(b) 1.5 to 3.5% by weight of the glass frit of claim 1, and
(c) an organic medium.

9: The conductive paste of claim 8, wherein the electrically conductive metal is selected from the group consisting of carbon, silver, gold, aluminum, platinum, palladium, tin, nickel, cadmium, gallium, indium, copper, zinc, iron, bismuth, cobalt, manganese, molybdenum, chromium, vanadium, titanium, tungsten, alloys thereof and mixtures thereof.

10: The conductive paste of claim 8, wherein the organic medium is selected from the group consisting of solvents, binders, surfactants, thixotropic agents, plasticizers, solubilizers, defoamers, desiccants, crosslinkers, complexing agents and/or conductive polymer particles and mixtures thereof.

11: The conductive paste of claim 8, wherein the electrically conductive metal is in the form of particles having a mean particle size in a range of from 10 nm to 100 μm.

12: A semiconductor substrate, comprising electrically conductive grid lines formed on the semiconductor substrate by the conductive paste of claim 8.
